(19) United States
(12) Patent Application Publication
(10) Pub. No.: US 2013/0161193 A1
(43) Pub. Date: Jun. 27, 2013

(54) MICROFLUIDIC SYSTEM WITH METERED FLUID LOADING SYSTEM FOR MICROFLUIDIC DEVICE

(71) Applicants: Adrian Marc Simon JACOBS, Reading (GB); Campbell Donald BROWN, Oxfordshire (GB); Benjamin James HADWEN, Oxford (GB); Jason Roderick HECTOR, Oxford (GB)

(72) Inventors: Adrian Marc Simon JACOBS, Reading (GB); Campbell Donald BROWN, Oxfordshire (GB); Benjamin James HADWEN, Oxford (GB); Jason Roderick HECTOR, Oxford (GB)

(73) Assignee: SHARP KABUSHIKI KAISHA, Osaka (JP)

(21) Appl. No.: 13/332,502

(22) Filed: Dec. 21, 2011

(51) Int. Cl. C25B 9/00; B81B 1/00

(52) U.S. Cl. 204/604

(57) ABSTRACT

A microfluidic system includes a microfluidic device; and a metered fluid loading system formed integrally with the microfluidic device and configured to load a discrete metered volume of fluid into the microfluidic device upon actuation.

### TECHNICAL FIELD

The present invention relates to a system for loading fluid into a microfluidic device. In particular it relates to a system that controls the volume of fluid loaded into such a device. It further to relates to a metered fluid loading system for Electrowetting-On-Dielectric (EWOD) devices.

### BACKGROUND ART

Microfluidics is a rapidly expanding field concerned with the manipulation and precise control of fluids on a small scale, often dealing with sub-microlitre volumes. There is growing interest in its application to chemical or biochemical assay and synthesis, both in research and production, and applied to healthcare diagnostics (“lab-on-a-chip”). In the latter case, the small nature of such devices allows rapid testing at point of need using much smaller clinical sample volumes than for traditional lab-based testing.

A microfluidic device can be identified by the fact that it has one or more channels (or more generally gaps) with at least one dimension less than 1 millimeter (mm). Common fluids used in microfluidic devices include whole blood samples, bacterial cell suspensions, protein or antibody solutions and various buffers. Microfluidic devices can be used to obtain a variety of interesting measurements including molecular diffusion coefficients, fluid viscosity, pH, chemical binding coefficients and enzyme reaction kinetics. Other applications for microfluidic devices include capillary electrophoresis, isoelectric focusing, immunoassays, enzymatic assays, flow cytometry, sample injection of proteins for analysis via mass spectrometry, PCR amplification, DNA analysis, cell manipulation, cell separation, cell patterning and chemical gradient formation. Many of these applications have utility for clinical diagnostics.

Many techniques are known for the manipulation of fluids on the sub-millimetre scale, characterised principally by laminar flow and dominance of surface forces over bulk forces. Most fall into the category of continuous flow systems, often employing cumbersome external pipework and pumps. Systems employing discrete droplets instead have the advantage of greater flexibility of function.

Electrowetting on dielectric (EWOD) is a well-known technique for manipulating discrete droplets of fluid by application of an electric field. It is thus a candidate technology for microfluidics for lab-on-a-chip technology. An introduction to the basic principles of the technology can be found in “Digital microfluidics: is a true lab-on-a-chip possible?”, (R. B. Fair, Microfluid Nanofluid (2007) 3:245-281). This review notes that methods for introducing fluids into the EWOD device are not discussed at length in the literature. It should be noted that this technology employs the use of hydrophobic internal surfaces. In general, therefore, it is energetically unfavourable for aqueous fluids to fill into such a device from outside by capillary action alone. Further, this may still be true when a voltage is applied and the device is in an actuated state. Capillary filling of non-polar fluids (e.g. oil) may be energetically favourable due to the lower surface tension at the liquid-solid interface.

A few examples exist of small microfluidic devices where fluid input mechanisms are described. U.S. Pat. No. 5,096,669 (Lauks et al.; published Mar. 17, 1992) shows such a device comprising an entrance hole and inlet channel for sample input coupled with an air bladder which pumps fluid around the device when actuated. It is does not describe how to input discrete droplets of fluid into the system nor does it describe a method of measuring or controlling the inputted volume of such droplets. Such control of input volume (known as “metering”) is important in avoiding overloading the device with excess fluid and helps in the accuracy of assays carried out where known volumes or volume ratios are required.

US20100282608 (Srinivasan et al.; published Nov. 11, 2010) describes an EWOD device comprising an upper section of two portions with an aperture through which fluids may enter. It does not describe how fluids may be forced into the device nor does it describe a method of measuring or controlling the inputted volume of such fluids. Related application US20100282609 (Pollack et al.; published Nov. 11, 2010) does describe a piston mechanism for inputting the fluid, but again does not describe a method of measuring or controlling the inputted volume of such fluid.

### SUMMARY OF INVENTION

A basic concept of the invention is an integrated fluid input mechanism for delivering a metered discrete volume of fluid into a microfluidic device.

Such a device may employ EWOD or AM-EWOD methods for fluid control.

In some embodiments the fluid input mechanism may operate by the displacement of a body of liquid or gas (e.g. air) to force fluid into the microfluidic device. In other embodiments the fluid input mechanism may operate by the expansion of a body of gas (e.g. air) to force fluid into the device.

In some embodiments the system may provide feedback via a fluid sensor, in order to verify that correct fluid input has occurred as part of an error detection method. In other embodiments temperature feedback may provide the operator with analogue control of the volume of fluid input.

In further embodiments closure means are provided for closing and sealing the system following initial fluid application and prior to actuation of the fluid input mechanism.

Advantages of the invention include:

Metering of the input fluid volume improves assay accuracy (ensuring sample and reagent are mixed in correct ratios), helps prevent overloading the device with too much fluid and hence leaves enough space for multiple assays or multiple assay operations on the same device

System is easy to use by a semi-skilled operator e.g. in a point of need setting—it does not rely on operator skill for accurate dispensing of sample and reagent, or prevention of leakage (a safety hazard)

Input mechanism is integrated into the microfluidic device for simplicity. The whole assembly is easy to fabricate at low cost, for example by injection moulding. This is important if the device is to be single-use disposable for diagnostic applications.

Provides means of sealing the device so that biological samples are enclosed within it and do not provide a contamination hazard

Less prone to leaks than systems using external pumping mechanisms

Methods for error detection to confirm correct filling

Analogue control of input volume in some embodiments

According to an aspect of the invention, a microfluidic system is provided which includes a microfluidic device; and a metered fluid loading system formed integrally with the microfluidic device and configured to load a discrete metered volume of fluid into the microfluidic device upon actuation.

According to another aspect, the metered fluid loading system includes a fluid input mechanism configured to actuate the metered fluid loading system.

In accordance with another aspect, the fluid input mechanism includes a bistable membrane actuator.

According to yet another aspect, the bistable membrane actuator is configured to actuate the metered fluid loading system as a result of being deformed from a first bistable state to a second bistable state.

In accordance with another aspect, the fluid input mechanism includes a deformable membrane actuator.

According to still another aspect, the deformable membrane actuator is configured to actuate the metered fluid loading system as a result of being deformed from an undeformed state to a deformed state.

In still another aspect, the fluid input mechanism further includes a limiter configured to limit an extent of deformation of the deformable membrane actuator.

According to another aspect, the fluid input mechanism includes a heater which effects an expansion of a body of gas to actuate the metered fluid loading system.

According to yet another aspect, the metered fluid loading system further including a temperature sensor as a feedback mechanism to control the expansion of the body of gas.

In accordance with another aspect, the metered fluid loading system includes a reservoir including an input channel through which the fluid is coupled from the reservoir to a gap of the microfluidic device.

According to still another aspect, the fluid input mechanism is operative to displace or expand a body of liquid or gas within the reservoir upon being actuated to force the fluid from the reservoir to the microfluidic device.

In accordance with yet another aspect, the system further includes a seal for forming an airtight seal between the fluid input mechanism and the reservoir.

According to yet another aspect, the fluid input mechanism is hinged to the reservoir permitting the fluid input mechanism to be opened and closed, and wherein when the fluid input mechanism is in an open position fluid which is to be loaded into the microfluidic device may be placed in the input channel, and when the fluid input mechanism is closed an airtight seal between the fluid input mechanism and the reservoir is formed.

In still another aspect, the system further includes a holding mechanism for holding the fluid input mechanism in the closed position.

In yet another aspect, the fluid input mechanism is coupled to the reservoir by sliding engagement.

According to yet another aspect, the reservoir includes a plurality of input channels.

In accordance with another aspect, the reservoir further includes a vent column.

According to still another aspect, the microfluidic device includes sensing elements to detect a presence of the fluid loaded by the metered fluid loading system.

In accordance with another aspect, the microfluidic device includes at least one hydrophobic surface in contact with the fluid loaded in the microfluidic device.

According to still another aspect, the microfluidic device is configured to draw fluid from the fluid loaded in the microfluidic device by controlling a hydrophobicity of a surface of the microfluidic device.

According to yet another aspect, the microfluidic device is an electrowetting on dielectric (EWOD) device.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

In the annexed drawings, like references indicate like parts or features:

FIG. 1 shows a cross-section of a known EWOD structure

FIG. 2 shows a projection view of a known EWOD array

FIGS. 3a, 3b and 3c show a cross section through a first embodiment of the invention

FIG. 4 shows a projection view of the reservoir in the first embodiment of the invention

FIGS. 5a and 5b show a cross section through a second embodiment of the invention illustrating a bistable actuator

FIGS. 6a and 6b show a cross section through a third embodiment of the invention illustrating a deformable membrane actuator

FIG. 7 shows a fourth embodiment of the invention illustrating interaction with an external controller

FIG. 8 shows a cross section through a fifth embodiment of the invention illustrating a heater

FIG. 9 shows a cross section through a sixth embodiment of the invention illustrating an implementation of a closure method

FIGS. 10a and 10b show a cross section through a seventh embodiment of the invention illustrating an implementation of a further closure method

FIGS. 11a and 11b show a cross section through an eighth embodiment of the invention illustrating an implementation of a yet further closure method

FIGS. 12a and 12b shows a ninth embodiment of the invention illustrating an combined sealing and actuation element

FIG. 13 illustrates the use of two input channels

FIG. 14 shows a tenth embodiment of the invention illustrating an alternative form of input channel

FIG. 15 shows an eleventh embodiment of the invention illustrating an example form of an electrode array

### DESCRIPTION OF REFERENCE NUMERALS

4 Conducting fluid droplet

6 Contact angle theta

8 Fluid

10 Droplet

16 Hydrophobic surface

20 Insulator layer

26 Hydrophobic layer

28 Electrode

32 Spacer

34 Non-conducting fluid

36 Top substrate

38 Electrode

42 Electrode array

44 Lower substrate

46 Reservoir

48 Input channel

50 Fluid input mechanism

52 Bistable actuator

54 Deformable membrane actuator

56 Reservoir with limiter

60 Device controller box

62 Actuation post

70 Lid

72 Heater

74 Temperature sensor

80 Clip

82 Seal

84 Hinge

90 Sliding hood

92 Runner

100 Sliding fluid input mechanism

110 Combined seal and deformable membrane actuator element

112 Deformable membrane actuator sub-element

114 Seal sub-element

120 Fill column

122 Vent column

130 High resolution electrode array

132 Low resolution electrode array

### DETAILED DESCRIPTION OF INVENTION

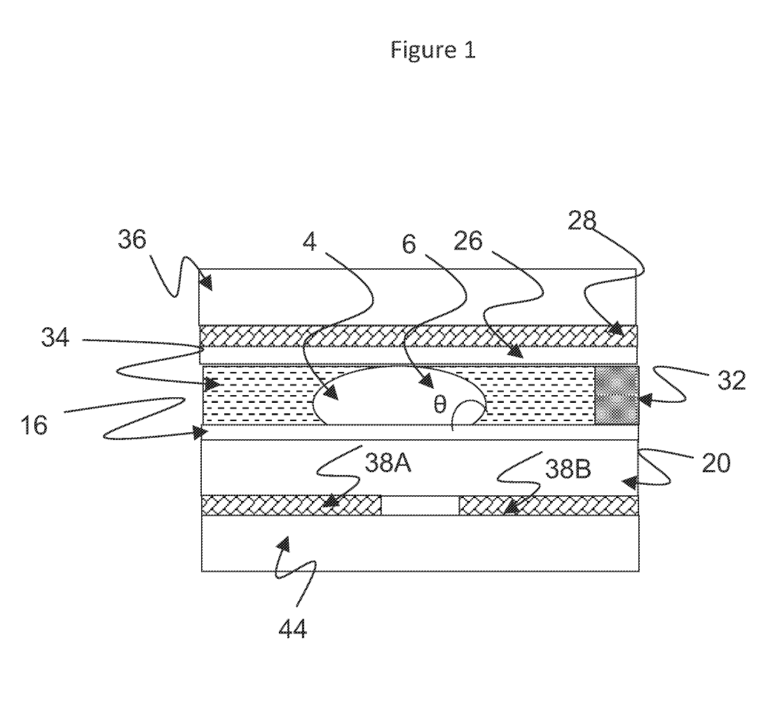

FIG. 1 shows a known structure in cross-section of an EWOD device.

The device includes a lower substrate 44 with a plurality of electrodes 38 (e.g., 38A and 38B) disposed upon it. These electrodes may have voltages applied directly or via a layer of thin-film electronics situated beneath the electrode layer (not shown) for example as in U.S. application Ser. No. 12/830,477 an “Array Element Circuit and Active Matrix Device, filed on Jul. 6, 2010. The droplet 4, consisting of a conducting (e.g. ionic or polar) material is constrained in a plane between the lower substrate 44 and a top substrate 36. The top substrate 36 has an electrode 28 thereon and a hydrophobic layer 26. A suitable gap between the two substrates may be realised by means of a spacer 32, and a non-conducting liquid 34 (e.g. dodecane oil) may be used to occupy the volume not occupied by the droplet 4. An insulator layer 20 disposed upon the lower substrate 44 separates the conductive electrodes 38A, 38B from a hydrophobic surface 16 upon which the droplet 4 sits with a contact angle θ 6. By appropriate design and operation, different voltages may be applied to different electrodes (e.g. electrodes 38A and 38B). The hydrophobicity of the surface 16 can be thus be controlled, thus facilitating droplet movement in the lateral plane between the two substrates.

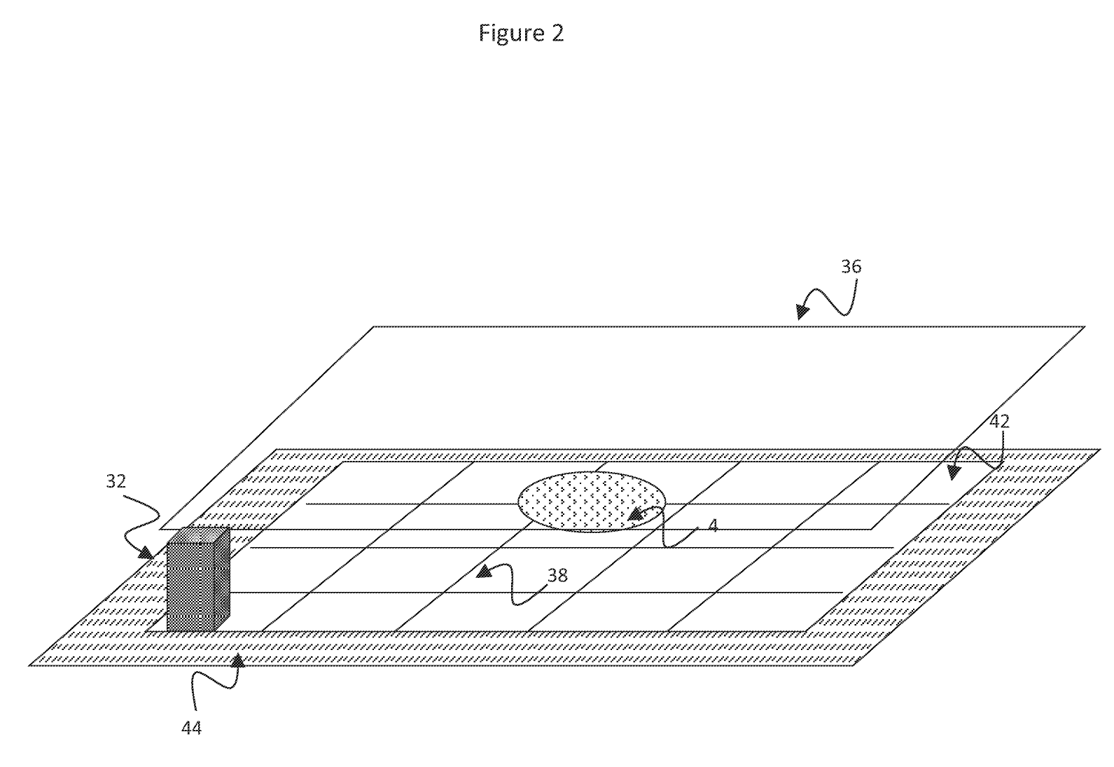

FIG. 2 illustrates an array of such elements. A plurality of electrodes 38 is arranged in an electrode array 42, having M×N elements where M and N may be any number. The droplet 4 is enclosed between the lower substrate 44 and the top substrate 36. Such an array may be realised by direct connection or else facilitated by the aforementioned thin-film electronics allowing a large array of independently addressing elements.

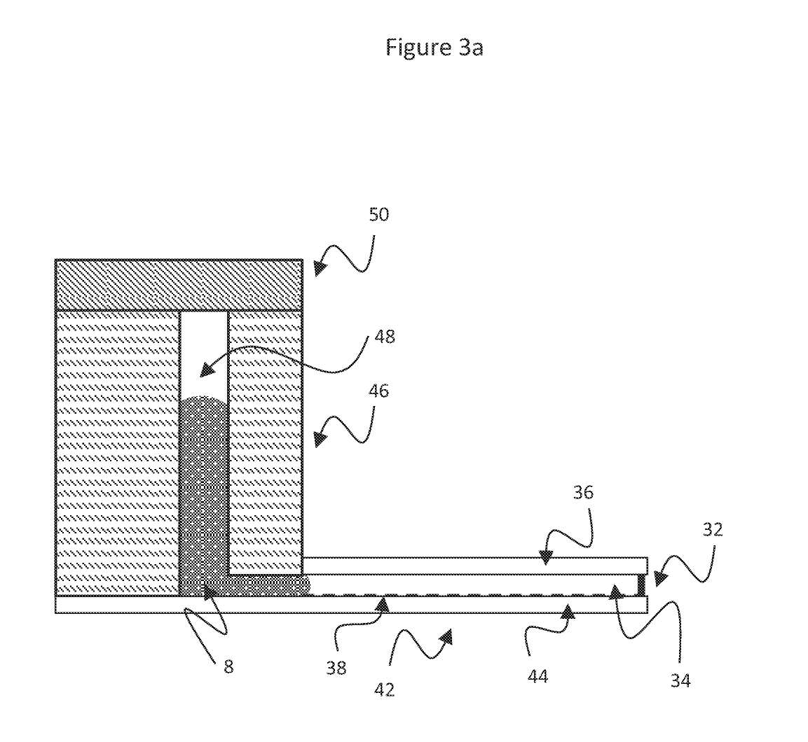

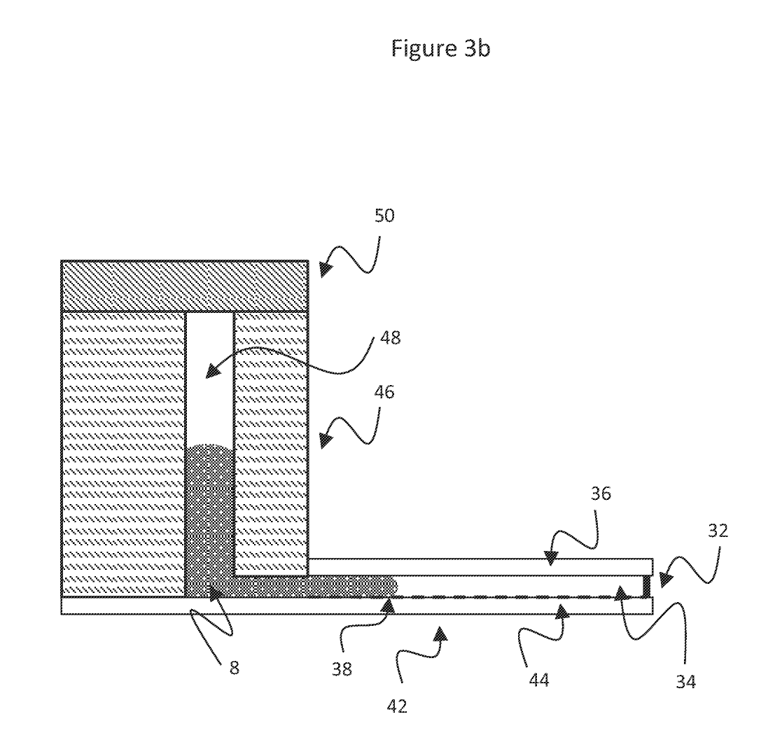

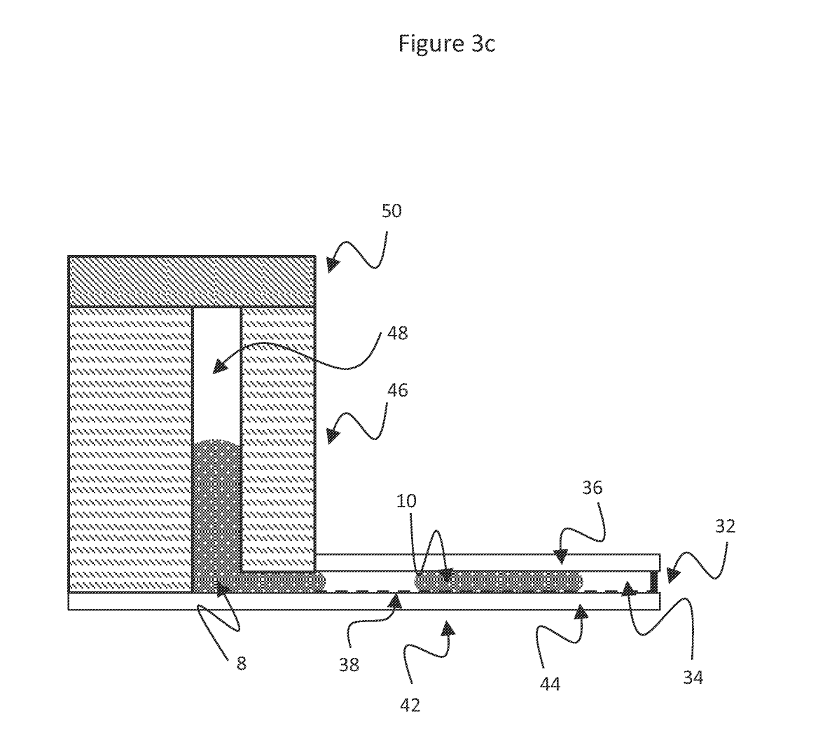

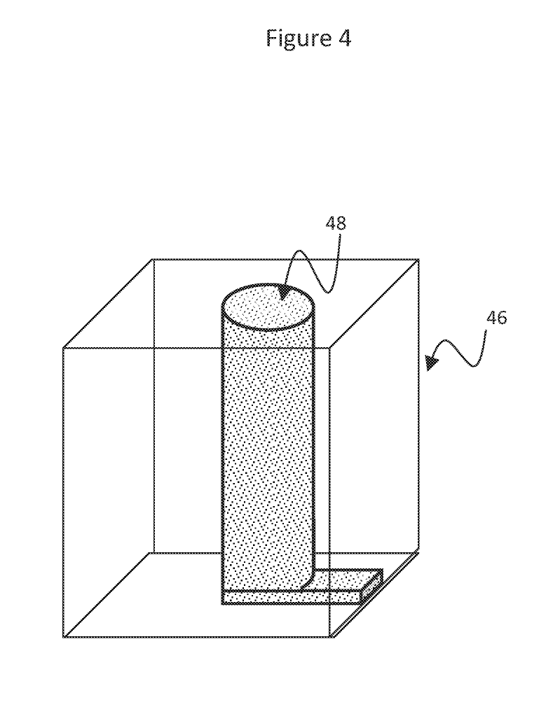

FIGS. 3a-3c illustrate a first embodiment of the invention. In addition to the EWOD components (insulator layers 20 and hydrophobic layers 26 are not shown for clarity) there is provided a metered fluid loading system for inputting fluids, and namely a discrete metered volume of fluid, into the EWOD device. The system preferably is formed integrally with the EWOD device, for example formed on the same lower substrate 44. The entire assembly may be fabricated at low cost, for example by injection moulding. The metered fluid loading system includes a reservoir 46 containing an input channel 48. Such a reservoir 46 is illustrated in projection view in FIG. 4. The input channel 48 is configured to couple the fluid from the reservoir 46 into a gap between the top substrate 36 and the lower substrate 44 of the EWOD device. The system further includes a fluid input mechanism, generally designated 50, which cooperates with the reservoir 46 and is in airtight contact with it. The fluid input mechanism 50 operates so as to cause the fluid 8 within the reservoir 46 to enter the EWOD device in the gap between the top substrate 36 and lower substrate 44. The fluid input mechanism 50 may be of any form which causes fluid of known volume to enter the system. Specific examples are given below.

FIG. 3a illustrates a first stage of the fluid input process where the fluid 8 substantially resides in the input channel 48 of the reservoir 46. When the fluid input mechanism 50 is activated the fluid 8 is forced into the gap between top substrate 36 and lower substrate 44 as illustrated in FIG. 3b. In a final stage illustrated in FIG. 3c a droplet 10 of the fluid 8 is drawn off from the main body of the fluid 8 by application of appropriate voltages on the electrode array 42 by virtue of the EWOD droplet control mechanism described previously (e.g., by application of different voltages to the electrodes 38 the hydrophobicity of the surface 16 can be controlled, thus facilitating movement of the fluid in the lateral plane between the substrates 36 and 44. This produces a droplet 10 which is independent of the original body of fluid 8 and may be manipulated as needed for subsequent operations. It may be convenient for the inputted volume of fluid 8, seen in FIG. 3b, to act as a master droplet from which a succession of smaller droplets 10 are drawn as needed, by the action of EWOD control.

The reservoir 46 may be formed of any suitable material that is compatible with the applied fluids. Compatibility implies that the material is not damaged or dissolved by the fluid 8, nor is the fluid contaminated by the material or substantially adheres to the material. For example, many engineering polymers may be used including PMMA (Poly(methyl methacrylate)), Nylon, PTFE (Polytetrafluoroethylene), PET (Polyethylene terephthalate), Polypropylene. It may be advantageous that the shallow horizontal section of the input channel 48 is narrower than the gap between top substrate 36 and bottom substrate 44. This would help this feature to act as a capillary stop for fluid in the channel so that fluid does not enter the gap between top substrate 36 and bottom substrate 44 until the fluid input mechanism 50 is actuated. The manner in which the fluid input mechanism 50 may be actuated is further discussed below.

It should be appreciated that such a system including a reservoir 46 and fluid input mechanism 50 in accordance with the invention could be applied to any other form of microfluidic system where fluid control is achieved by methods other than EWOD.

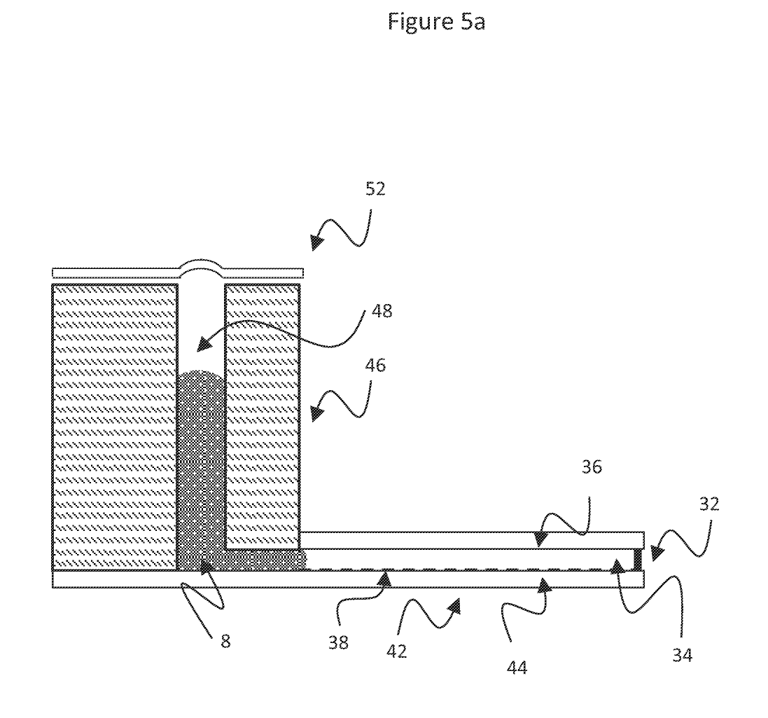

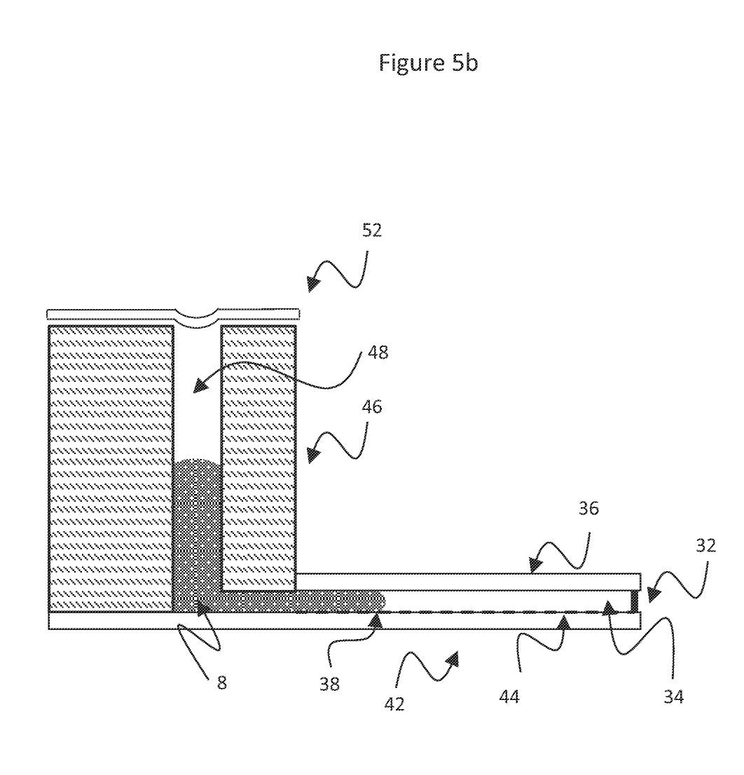

FIGS. 5a-5b illustrate a second embodiment of the invention providing a specific implementation of the fluid input mechanism. The fluid input mechanism includes a bistable actuator 52 which may readily adopt either a first or second shape. For example, the first shape (first bistable state) may be a convex section of a sphere or ellipsoid (as shown in FIG. 5a) whilst the second shape (second bistable state) may be a concave section of a sphere or ellipsoid (as shown in FIG. 5b). Such a bistable actuator 52 may be made, for example, of a suitable semi-flexible material such that on application of an external force it will deform from the first shape to the second shape. Suitable materials include polystyrene copolymers such as High Impact Polystyrene. This force may be applied for example by an external rigid elongate element (not shown) pressed momentarily against the actuator 52. FIG. 5a illustrates the bistable actuator 52 in its first shape. FIG. 5b illustrates the bistable actuator 52 in its second shape following application of an external force to the top of the actuator. The bistable actuator 52 works in cooperation with the input channel 48. The first and second shapes must be chosen so as to tend to compress the air (or other suitable gas) in the input channel 48 following the change from first shape to second shape. As the total system is not sealed, this increase in air pressure cannot be sustained. The air will, therefore, tend to approximately maintain its original volume and pressure, resulting in a translation of this volume of air and hence of the fluid 8 in the input channel 48 in response to the change in shape. This in turn forces the fluid 8 into the gap between top substrate 36 and lower substrate 44 thus achieving input of fluid 8 into the microfluidic device. As the volumes of the first and second shapes are known, the volume of input fluid 8 introduced into the microfluidic device via the gap between the top substrate 36 and the lower substrate 44 is known and fixed, and thus metered. This has the advantage that the volume is pre-defined at manufacture and not dependent on the motion or position of the element pressing on the actuator 52.

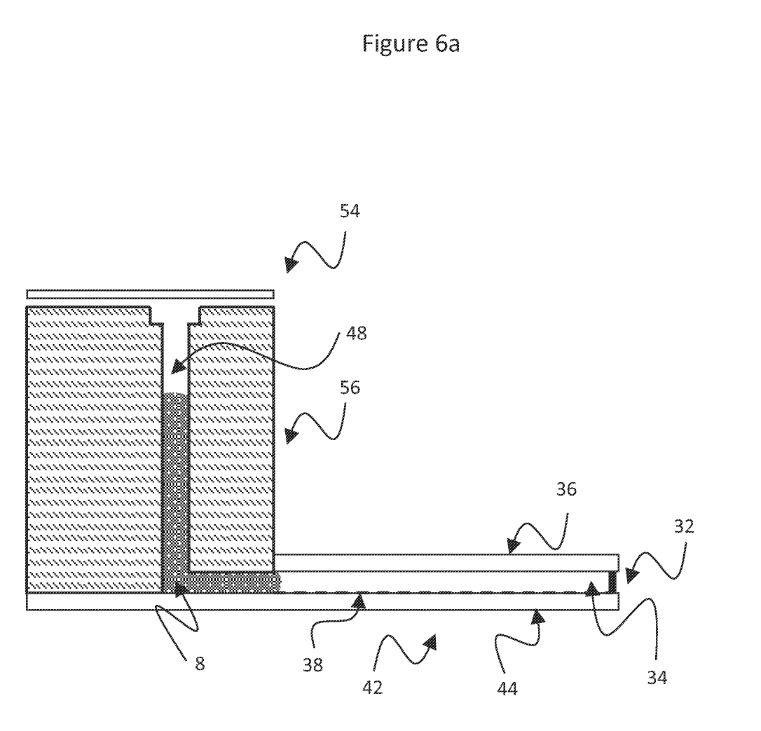

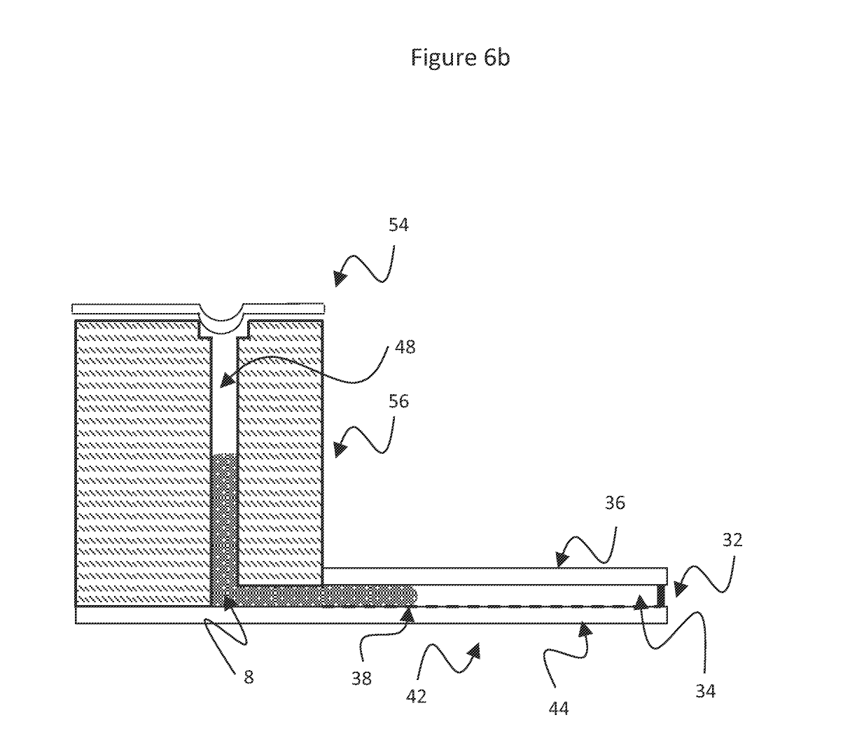

FIGS. 6a-6b illustrate a third embodiment of the invention providing a further implementation of the fluid input mechanism. The fluid input mechanism includes a deformable membrane actuator 54 which is made of a suitable material capable of being deformed on application of an external force. This force may be applied for example by an external rigid elongate element (not shown) pressed against the actuator 54. In some applications it is useful if this deformation is reversible on removal of the force. Suitable materials from which the actuator 54 may be made include elastomers such as silicone rubbers, natural rubber, nitrile rubbers, or fluoroelastomers such as copolymers of hexafluoropropylene (HFP) and vinylidene fluoride (VDF or VF2). The actuator 54 is coupled to a reservoir 56 which differs from the reservoir of previous embodiments in that the top of the input channel 48 is structured as to form a limiter which limits the extent of deformation of the actuator 54. In the embodiment of FIGS. 6a-6b, the limiter is represented by a recessed step which prevents further deformation of the actuator 54. FIG. 6a shows the actuator 54 in an undeformed state. FIG. 6b shows the system during application of an external force and the actuator 54 is seen to have deformed in a manner than tends to compress the air in the input channel 48. By the same principle as described for the embodiment of FIG. 5, fluid 8 is forced into the gap between top substrate 36 and bottom substrate 44 thus achieving input of fluid 8 into the system The known volume of this limiter feature sets a maximum value for the volume of input fluid, and thus again the loading of the fluid into the EWOD device is metered.

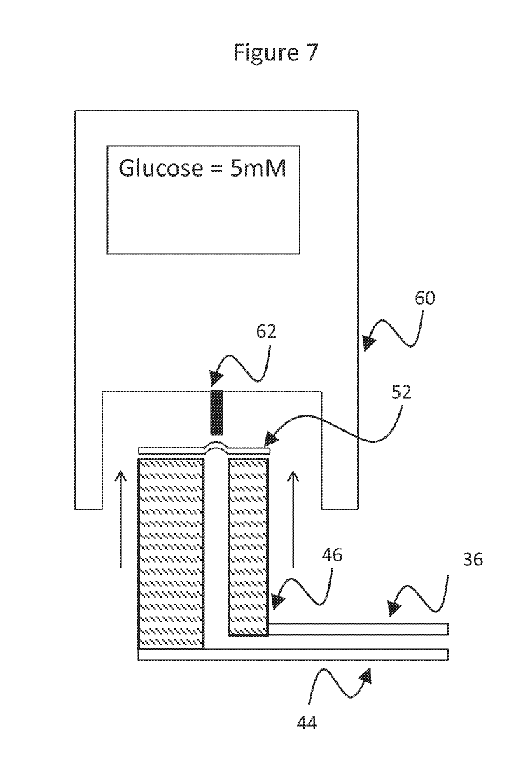

FIG. 7 illustrates a fourth embodiment of the invention which represents an example implementation of any of the preceding embodiments. It shows a device controller box 60 which includes a box containing electronics to control the EWOD operation (or other microfluidic device) and may also include electronic or optical means for detection of the result of some assay carried out on the microfluidic device (for example a display with a glucose measurement is shown for illustration purposes). It may further be connected to a computer (not shown) for control and readout functions. There is further an actuation post 62 within an aperture of the controller box 60. It is affixed to the box in such a position that when the microfluidic device is inserted into the aperture of the controller box 60 for the purposes of control and readout, the post 62 is brought into contact with the actuator 52 (or 54) thus applying a force and causing the actuator to be actuated in the same operation.

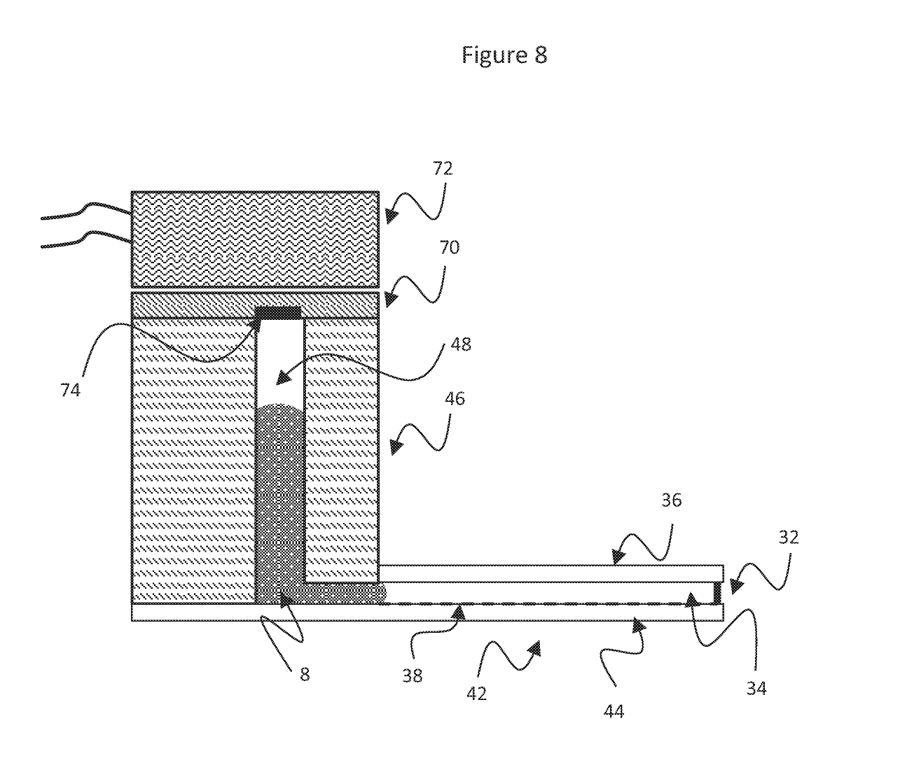

FIG. 8 illustrates a fifth embodiment of the invention providing a yet further implementation of the fluid input mechanism. It differs from earlier embodiments in that the reservoir 46 has a sealed non-deformable lid 70 serving as the fluid input mechanism together with a heater 72. The heater 72 provides heating for example by electrical means. The heater 72 may be attached to the lid 70, as illustrated, or else to the side of reservoir 46 or underside of substrate 44, in all cases to be in good thermal contact with the reservoir 46. Alternatively, the heater may be realised by forming a thin conductor layer on the substrate 44 positioned under the reservoir 46. In any of these examples a temperature sensor 74 may also be included as a feedback mechanism to ensure the desired temperature is reached. This has the advantage of allowing the user analogue control of the volume of fluid inputted.

The air in the input channel 48 will approximately follow the ideal gas law:

PV=nRT

where P is pressure, V is volume, n is the number of moles of the gas, R is the ideal gas constant and T is the temperature.
As this is a trapped pocket of air then n is fixed. As the total system is not sealed, no increase in air pressure can be sustained. Therefore, if the temperature T is increased then the volume of air will increase in proportion i.e.

V₀/V₁=T₀/T₁ or ΔV/V₀=ΔT/T₀

where ΔV & ΔT are changes in V & T and V₀ & T₀ and V₁ & T₁ are initial and final values respectively.
This expansion of the air will cause the fluid 8 to be displaced. This in turn forces fluid 8 into the gap between top substrate 36 and bottom substrate 44 thus achieving input of fluid into the device. The volume of fluid input is thus known and controllable by appropriate controller of the heater 72 so as to introduce a metered volume of fluid. Of course in another embodiment, a gas other than air may occupy the fluid input channel.

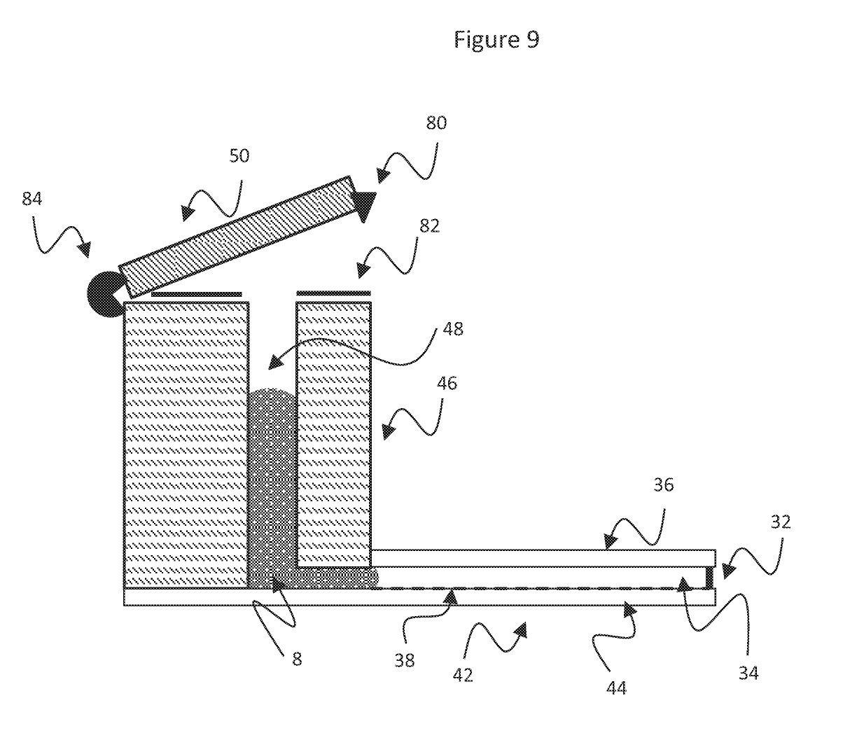

In the foregoing embodiments the fluid input mechanism 50 (52,54,70) is sealed to the reservoir 46. Naturally this sealing must occur after the fluid is placed in the input channel. FIG. 9 illustrates a sixth embodiment of the invention showing a mechanism for achieving this sealing which may be applied to any of the foregoing embodiments. The fluid input mechanism 50 is attached to the reservoir 46 via a hinge 84 which allows said mechanism to rest in an open (as illustrated) or closed position. The mechanism 50 also includes a clip 80 which mates with a matching structure (not shown) on the reservoir 46 to hold the mechanism 50 in a closed position. There is further provided a seal 82, for example a rubber or elastomer gasket, which may be attached to either the reservoir 46 (as illustrated) or the fluid input mechanism 50. With the mechanism 50 in an open position the fluid 8 may be placed in the input channel 48, for example by dispensing from a pipette. In the case of a blood sample alternatively it may be applied directly from a pricked fingertip. The mechanism 50 is then clipped into a closed position forming a seal against the reservoir 46 via the seal 82.

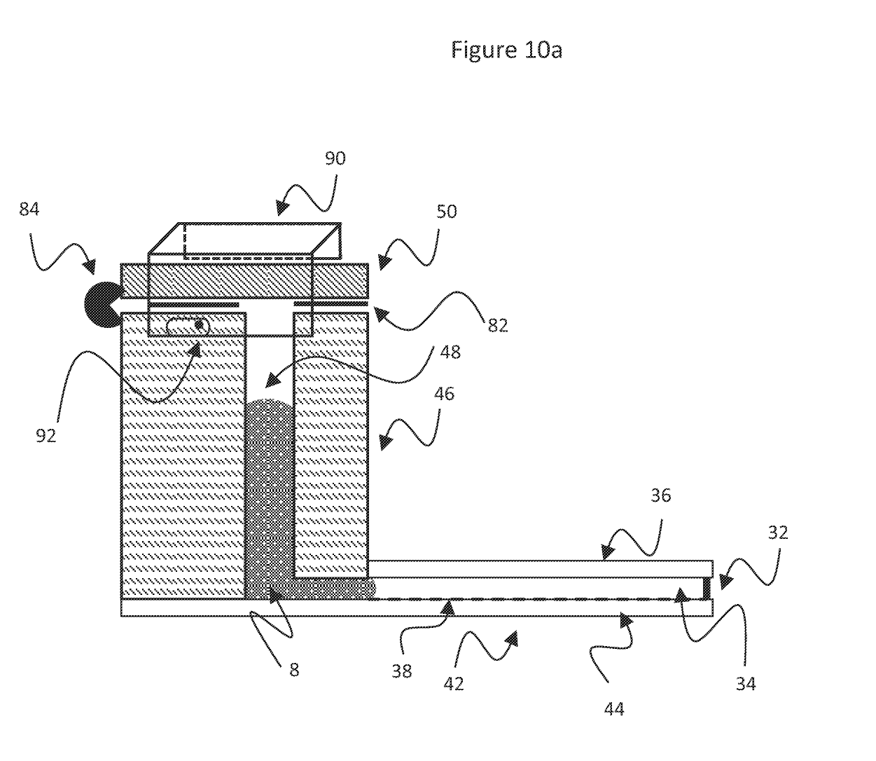

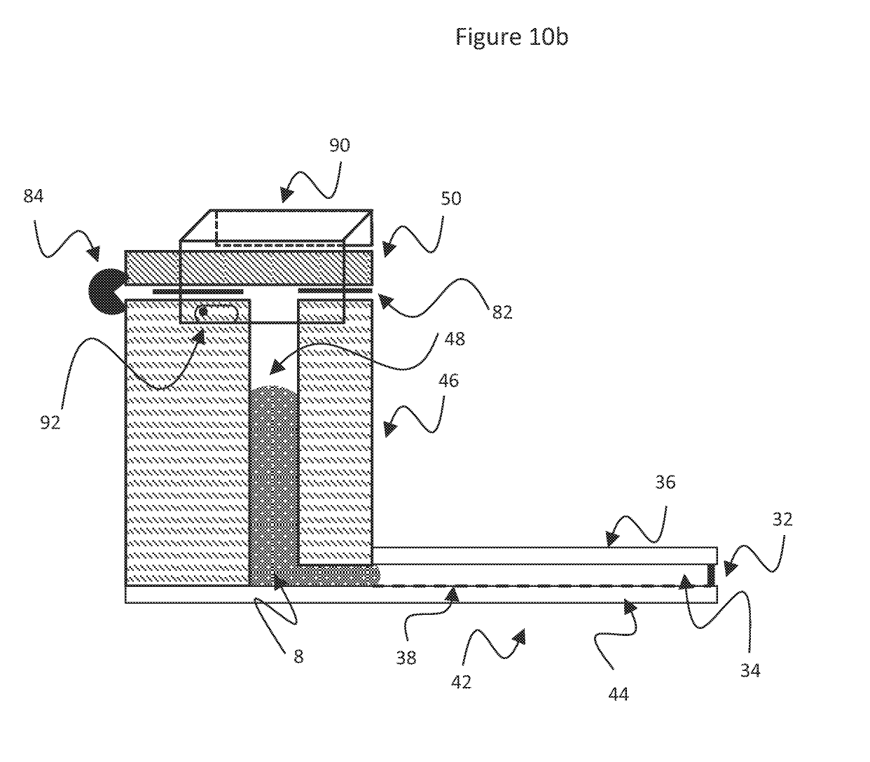

FIGS. 10a-10b illustrate a seventh embodiment of the invention showing a further implementation of sealing the fluid input mechanism 50 (52,54,70) to the reservoir 46 in any of the foregoing embodiments. This differs from the embodiment of FIG. 9 by having a different mechanism for holding the mechanism 50 in a closed sealed position. Instead of the clip 80, there is a sliding hood 90 arranged around the mechanism 50 and a runner 92 formed on the side of the reservoir 46. FIG. 10a shows the system when the mechanism 50 is in the closed position. In this position the sliding hood 90 mates with the runner 92. The sliding hood may then be moved into a second position, as shown in FIG. 10b, which locks the mechanism 50 in place and seals it in place. It is further possible to design the sliding hood 90 so that it obscures the movable element of the mechanism 50 in its first position but reveals it in the second position. This helps prevent accidental actuation until the mechanism 50 is locked in place.

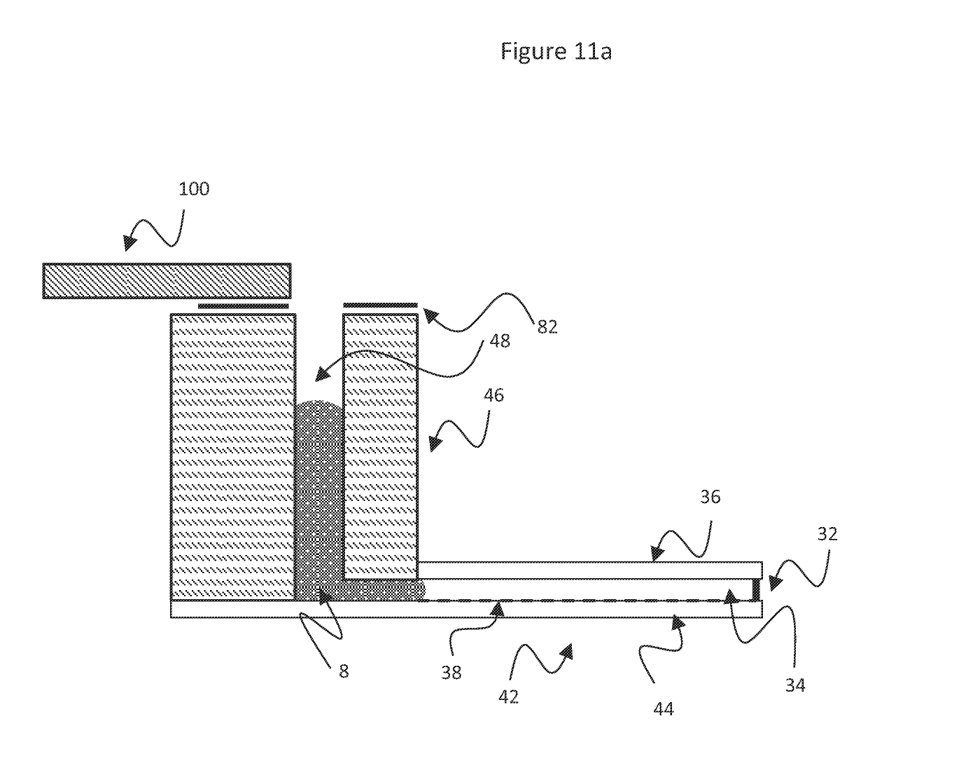

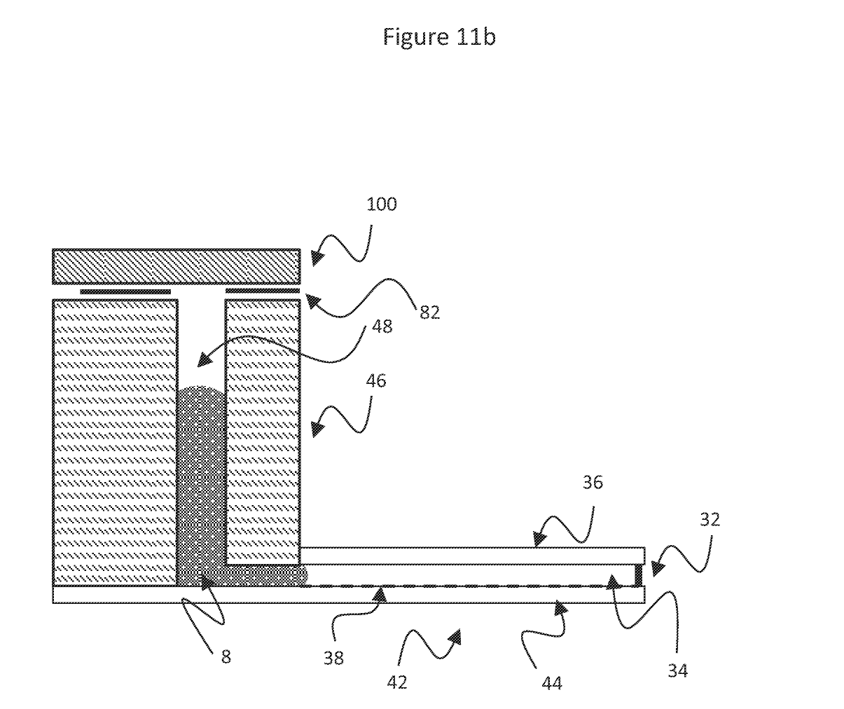

FIGS. 11a-11b illustrate an eighth embodiment of the invention showing a further implementation of sealing the fluid input mechanism to the reservoir 46 which may be utilized in conjunction with any of the foregoing embodiments. In this case the fluid input mechanism is a sliding fluid input mechanism 100 attached to the reservoir 46 via a runner (not shown) on the reservoir 46 so as to be in sliding engagement. FIG. 11a shows the mechanism 100 where the fluid may be input. It then may be moved into a closed position (shown in FIG. 11b) forming a seal with the reservoir 46.

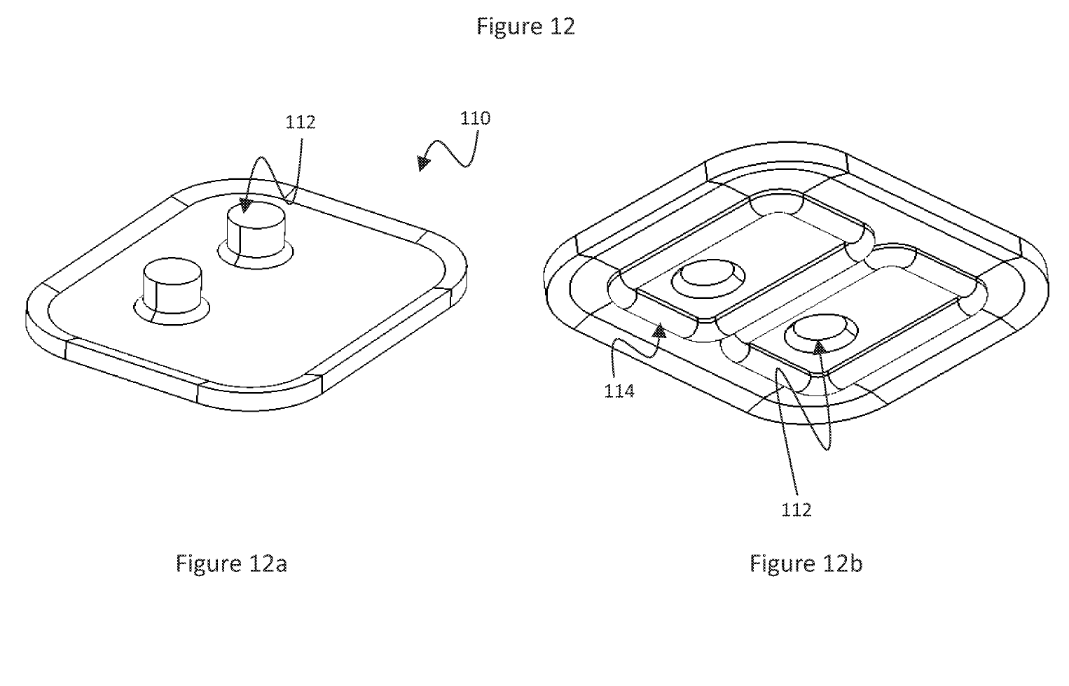

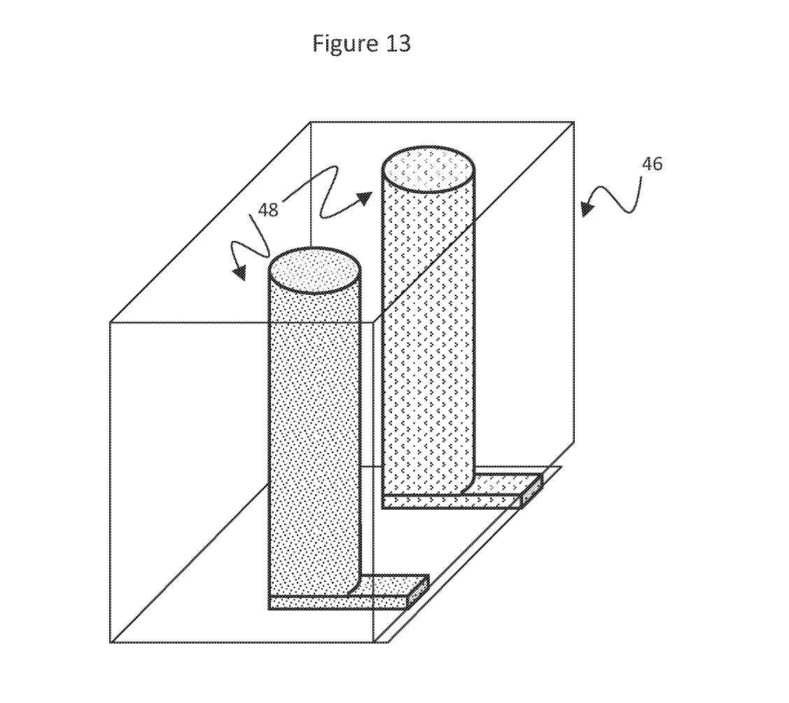

FIG. 12 illustrates a ninth embodiment and show a means of combining the deformable membrane actuator 54 and seal 82 of the foregoing embodiments into one element 110. This may have advantages in ease of manufacture and may be made of any suitable deformable material such as elastomer or silicone rubber as previously described. FIGS. 12a and 12b show a top side and under side of such an element, respectively. It comprises a deformable membrane actuator sub-element 112 and seal sub-element 114. This element may be further encased in a rigid housing (not shown) to form the fluid input mechanism 50 and seal 82 combined of embodiments in FIGS. 9-11.

Previous embodiments have illustrated a reservoir with a single input channel. However, it is also possible to form multiple input channels within the same reservoir block. This may be useful to allow the separate input of sample and several reagents. The element 110 of FIG. 12 includes a deformable membrane actuator sub-element 112 and sub-element 114 for two separate channels, although more channels may be included as will be appreciated. An example of a reservoir 46 with two input channels 48 is shown in FIG. 13.

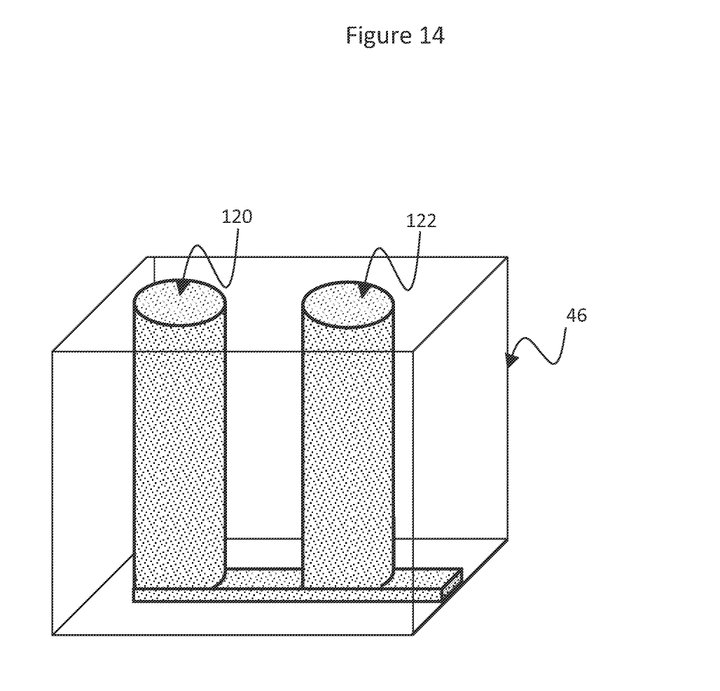

FIG. 14 illustrates a tenth embodiment of the invention which has a different shape to the input channel and may be applied to any of the foregoing embodiments. The previously described input channel 48 included a single vertical column connected to a shallow horizontal channel which brought fluid up to the gap between substrates 36 and 44. When the fluid is placed in the input channel, the air that it displaces must be allowed to escape through the system. In the present embodiment there are two vertical columns connected by a shallow horizontal channel. The fluid is placed in the fill column 120 and air is able to escape through the vent column 122. This may be useful in applications where the gap between substrates 36 and 44 is completely filled with non-conducting fluid 34 prior to filling of aqueous fluid 8. Without these two columns 120 and 122 this sequence would not be possible as there would be no route for air to escape.

In any of the foregoing embodiments the electrode array 42 may also include sensing elements which would detect the presence of the droplet 10. Further, such elements may measure the impedance of the fluid that is present (for example, as described in the aforementioned U.S. application Ser. No. 12/830,477). Use of such sensing elements would provide confirmation that filling had occurred correctly and serve as an error detection mechanism. For example, if filling of the fluid was insufficient or had failed entirely, then detection of this could be used to automatically trigger, or indicate to an operator, a repeat of the filling operation. In the case of multiple input channels being present where one was malfunctioning, an alternative channel could automatically be selected.

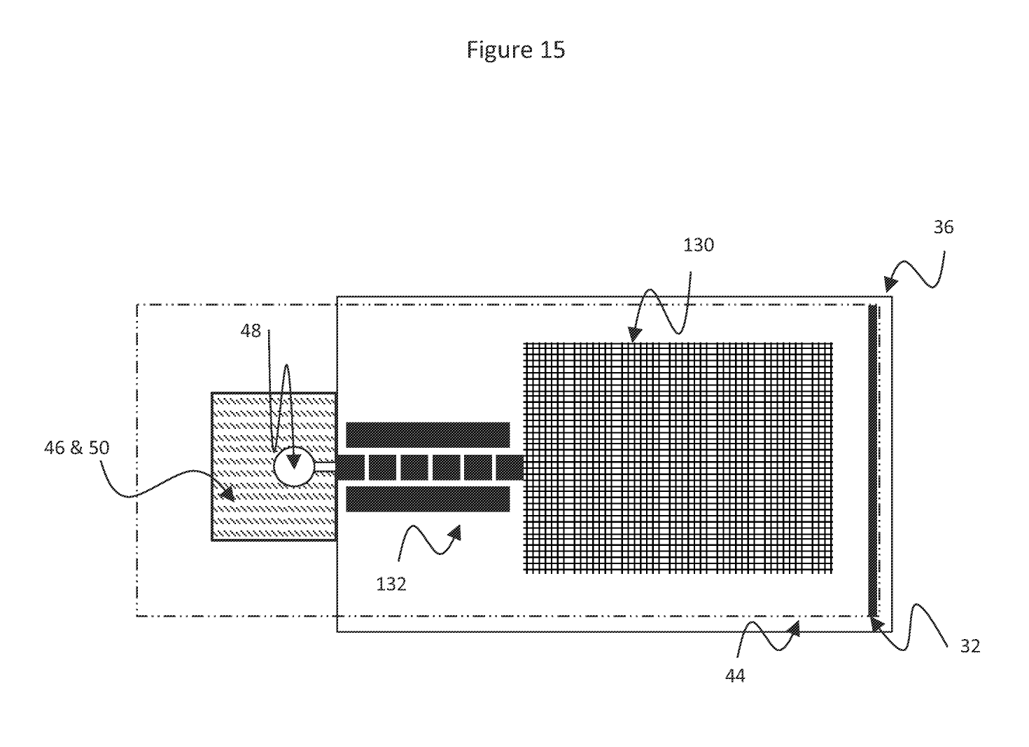

FIG. 15 illustrates an eleventh embodiment of the invention showing an aerial view of a system similar to that of the embodiment of FIG. 3. Here a possible example of the electrode array 42 is shown in more detail. It may be advantageous that this array comprises a high resolution electrode array 130 and a low resolution electrode array 132 formed on the lower substrate 44. The low resolution electrode array 132 (comprising larger electrode pads) may be used to draw out and control the relatively large droplets that are drawn directly from the reservoir 46. These electrodes provide a linear path to separate these droplets from the main body of fluid 8 in the reservoir 46 and transport them to the main high resolution electrode array 130. In this illustrative example elongate electrodes are positioned either side of the main path within the low resolution electrode array 132 to help prevent fluid accidentally spreading beyond the bounds of the path. The high resolution array 130 (comprising smaller electrode pads) may then be preserved for splitting these droplets into sub-droplets and carrying out subsequent operations for example a chemical assay.

It will be further apparent that the microfluidic device described could form part of a complete lab-on-a-chip system as described in prior art. Within such a system, the fluids input and manipulated in the device could be chemical or biological fluids, e.g. blood, saliva, urine, etc. or any test reagent, and that the whole arrangement could be configured to perform a chemical or biological test or to synthesize a chemical or biochemical compound.

Although the invention has been shown and described with respect to a certain embodiment or embodiments, equivalent alterations and modifications may occur to others skilled in the art upon the reading and understanding of this specification and the annexed drawings. For example, while the above embodiments rely primarily on the displacement or expansion of air or other suitable gas to force the fluid from the input channel into the microfluidic device, a suitable liquid may also be employed. Suitable liquids include those which within the input channel remain separated from the fluid which is to be loaded into the microfluidic device. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

The microfluidic device could form a part of a lab-on-a-chip system. Such devices could be used in manipulating, reacting and sensing chemical, biochemical or physiological materials. Applications include healthcare diagnostic testing, chemical or biochemical material synthesis, proteomics, tools for research in life sciences and forensic science.

1. A microfluidic system, comprising:
a microfluidic device; and
a metered fluid loading system formed integrally with the microfluidic device and configured to load a discrete metered volume of fluid into the microfluidic device upon actuation.

2. The microfluidic system according to claim 1, wherein the metered fluid loading system includes a fluid input mechanism configured to actuate the metered fluid loading system.

3. The microfluidic system according to claim 2, wherein the fluid input mechanism comprises a bistable membrane actuator.

4. The microfluidic system according to claim 3, wherein the bistable membrane actuator is configured to actuate the metered fluid loading system as a result of being deformed from a first bistable state to a second bistable state.

5. The microfluidic system according to claim 2, wherein the fluid input mechanism comprises a deformable membrane actuator.

6. The microfluidic system according to claim 5, wherein the deformable membrane actuator is configured to actuate the metered fluid loading system as a result of being deformed from an undeformed state to a deformed state.

7. The microfluidic system according to claim 6, wherein the fluid input mechanism further comprises a limiter configured to limit an extent of deformation of the deformable membrane actuator.

8. The microfluidic system according to claim 2, wherein the fluid input mechanism comprises a heater which effects an expansion of a body of gas to actuate the metered fluid loading system.

9. The microfluidic system according to claim 8, the metered fluid loading system further including a temperature sensor as a feedback mechanism to control the expansion of the body of gas.

10. The microfluidic system according to claim 2, wherein the metered fluid loading system comprises a reservoir including an input channel through which the fluid is coupled from the reservoir to a gap of the microfluidic device.

11. The microfluidic system according to claim 10, wherein the fluid input mechanism is operative to displace or expand a body of liquid or gas within the reservoir upon being actuated to force the fluid from the reservoir to the microfluidic device.

12. The microfluidic system according to claim 10, further comprising a seal for forming an airtight seal between the fluid input mechanism and the reservoir.

13. The microfluidic system according to claim 10, wherein the fluid input mechanism is hinged to the reservoir permitting the fluid input mechanism to be opened and closed, and wherein when the fluid input mechanism is in an open position fluid which is to be loaded into the microfluidic device may be placed in the input channel, and when the fluid input mechanism is closed an airtight seal between the fluid input mechanism and the reservoir is formed.

14. The microfluidic system according to claim 13, further comprising a holding mechanism for holding the fluid input mechanism in the closed position.

15. The microfluidic system according to claim 10, wherein the fluid input mechanism is coupled to the reservoir by sliding engagement.

16. The microfluidic system according to claim 10, wherein the reservoir comprises a plurality of input channels.

17. The microfluidic system according to claim 10, wherein the reservoir further comprises a vent column.

18. The microfluidic system according to claim 1, wherein the microfluidic device includes sensing elements to detect a presence of the fluid loaded by the metered fluid loading system.

19. The microfluidic system according to claim 1, wherein the microfluidic device comprises at least one hydrophobic surface in contact with the fluid loaded in the microfluidic device.

20. The microfluidic system according to claim 1, wherein the microfluidic device is configured to draw fluid from the fluid loaded in the microfluidic device by controlling a hydrophobicity of a surface of the microfluidic device.

21. The microfluidic system according to claim 1, wherein the microfluidic device is an electrowetting on dielectric (EWOD) device.
